(19) United States
(12) Patent Application Publication
(10) Pub. No.: US 2014/0044962 A1
(43) Pub. Date: Feb. 13, 2014

(54) ADHESIVE COMPOSITION, FILM ADHESIVE, AND BONDING METHOD

(71) Applicant: Tokyo Ohka Kogyo Co., Ltd., Kawasaki-shi (JP)

(72) Inventors: Takuya Noguchi, Kawasaki-shi (JP); Toshiyuki Ogata, Kawasaki-shi (JP); Atsushi Kubo, Kawasaki-shi (JP); Hirofumi Imai, Kawasaki-shi (JP); Takahiro Yoshioka, Kawasaki-shi (JP)

(73) Assignee: Tokyo Ohka Kogyo Co., Ltd., Kawasaki-shi (JP)

(21) Appl. No.: 13/960,645

(22) Filed: Aug. 6, 2013

(30) Foreign Application Priority Data
Aug. 13, 2012 (JP) 2012-179312
Jun. 3, 2013 (JP) 2013-117292

(51) Int. Cl. H01L 21/683

(52) U.S. Cl. CPC H01L 21/6836
USPC 428/355 EN; 524/578; 524/575; 524/570

(57) ABSTRACT

An adhesive composition including an elastomer as a main component, an adhesive layer prepared from the adhesive composition having (i) a storage modulus (G′) of not less than 20,000 Pa at 220° C. and/or (ii) a loss modulus (G″) of not less than 20,000 Pa at 220° C.

This application claims priority under 35 U.S.C. §119(a)-(d) to Japanese Patent Application No. 2012-179312, filed Aug. 13, 2012; and Japanese Patent Application No. 2013-117292, filed Jun. 3, 2013, the entire contents of which are hereby incorporated by reference.

### TECHNICAL FIELD

The present invention relates to an adhesive composition, a film adhesive, and a bonding method.

### BACKGROUND ART

As mobile phones, digital AV devices, IC cards and the like are highly functionalized in recent years, it is more demanded that a semiconductor silicon chip (hereafter referred to as “chip”) be highly integrated in a package by making a mounted chip smaller and thinner. For instance, there is a demand for further thinning of an integrated circuit obtained by packaging a plurality of chips, such as CSP (chip size package) and MCP (multi-chip package). In order to fulfill high integration of chips in a package, it is necessary to thin each chip down to a range of 25 μm to 150 μm.

However, a semiconductor wafer (hereafter referred to as “wafer”) serving as a base of a chip becomes thin by grinding. Therefore, strength of the wafer decreases. This is likely to result in a crack or a warpage in the wafer. Furthermore, it is difficult to automatically carry the wafer whose strength decreases due to its smaller thickness. Therefore, it is necessary to manually carry the wafer and it is troublesome to handle the wafer.

For this reason, there has been developed a wafer handling system for reinforcement of a wafer, by which to adhere a plate called “support plate” which is composed of glass, silicon, hard plastic or the like, to a wafer to be ground, thereby preventing a crack and a warpage in the wafer. Since the wafer handling system can reinforce a wafer, it is possible to automatically carry a semiconductor wafer having been made thinner.

In the wafer handling system, (i) a wafer and a support plate are adhered together with the use of various kinds of adhesive tape, thermoplastic resins or adhesives, (ii) the wafer adhered to the support plate is thinned, and then (iii) the support plate is separated from the wafer prior to dicing of the wafer. In a case where an adhesive agent is used to bond the wafer and the support plate together, the wafer is separated from the support plate by dissolving the adhesive agent.

Note here that, in recent years, there has been developed, as such an adhesive composition, a cycloolefinic resin composition which is composed of (i) a cycloolefinic resin (A1) and (ii) a low-molecular weight cycloolefinic resin (A2) having a number-average molecular weight of 10,000 or less (Patent Literature 1).

### CITATION LIST

Patent Literature 1
PCT International Publication No. WO2007/132641 A1 Pamphlet (International Publication Date: Nov. 22, 2007)

### SUMMARY OF INVENTION

### Technical Problem

However, in a case where a laminate is formed by bonding the wafer and the support plate with use of the cycloolefinic resin composition described in Patent Literature 1, the laminate greatly warps when subjected to a heating process.

The present invention is made in view of the problem above, and an object of the present invention is to provide (i) an adhesive composition capable of suppressing warpage of a laminate when the laminate is subjected to a heating process, (ii) a film adhesive that includes an adhesive layer containing the adhesive composition, and (iii) a bonding method using the adhesive composition.

### Solution to Problem

In order to attain the above object, an adhesive composition in accordance with the present invention is an adhesive composition including an elastomer as a main component, wherein an adhesive layer prepared from said adhesive composition has (i) a storage modulus (G′) of not less than 20,000 Pa at 220° C. and/or (ii) a loss modulus (G″) of not less than 20,000 Pa at 220° C.

A film adhesive in accordance with the present invention includes a film and an adhesive layer provided on the film, the adhesive layer containing an adhesive composition.

A method for adhering in accordance with the present invention includes the step of bonding a support to a wafer with use of an adhesive composition.

### Advantageous Effects of Invention

According to the present invention, it is possible to provide an adhesive composition which suppresses warpage of a laminate even when the laminate is subjected to a heating process.

### DESCRIPTION OF EMBODIMENTS

[Adhesive Composition]

An adhesive composition in accordance with the present invention includes an elastomer as a main component, wherein an adhesive layer prepared from said adhesive composition has (i) a storage modulus (G′) of not less than 20,000 Pa at 220° C. and/or (ii) a loss modulus (G″) of not less than 20,000 Pa at 220° C.

According to a conventional adhesive composition, there has been the following problem. That is, an adhesive agent becomes fluid by heat in a high-temperature range. Therefore, a laminate (wafer) warps (i) depending on how the wafer is held in the heating process and (ii) due to a stress resulting from a difference in linear expansion coefficient between the wafer and a support which are bonded together to form the laminate.

In contrast, according to the adhesive composition of the present invention, it is possible to suppress warpage of a laminate even when the laminate is subjected to a heating process, because the adhesive composition of the present invention satisfies at least one of the following requirements: an adhesive layer prepared from said adhesive composition has (i) a storage modulus (G′) of not less than 20,000 Pa at 220° C. and/or (ii) a loss modulus (G″) of not less than 20,000 Pa at 220° C. In other words, since the adhesive layer prepared from the adhesive composition of the present invention has a high storage modulus (G′) and/or a high loss modulus (G″) even when being heated, the adhesive layer is less likely to become fluid by heat and less likely to deform. Therefore, a difference in linear expansion coefficient between layers of the laminate causes less stress, and thus the laminate is less likely to warp.

Furthermore, it is more preferable that (i) the storage modulus (G′) at 220° C. of the adhesive layer prepared from the adhesive composition of the present invention is not less than 50,000 Pa and/or (ii) the loss modulus (G″) of the adhesive layer is not less than 50,000 Pa at 220° C.

Note that, although there are no particular upper limits on the storage modulus (G′) and the loss modulus (G″), the storage modulus (G′) at 220° C. is not more than 1,000,000 and, in view of adhesiveness between a wafer and a support, is preferably not more than 500,000, and is particularly preferably not more than 200,000. Furthermore, the loss modulus (G″) at 220° C. is not more than 1,000,000 and, in view of adhesiveness between a wafer and a support, is preferably not more than 500,000 and is particularly preferably not more than 200,000.

Note here that the storage modulus and the loss modulus are obtained by measuring, with a known dynamic viscoelasticity measuring instrument, a sample of the adhesive layer having a thickness of 1 mm and a diameter of 25 mm while heating the sample at a heating rate of 5° C. per minute from 50° C. to 250° C. with a shear condition of 10 Hz.

(Elastomer)

An elastomer which is contained in the adhesive composition of the present invention is a main component of the adhesive composition, and is not limited provided that an adhesive layer prepared from the adhesive composition has (i) a storage modulus (G′) of not less than 20,000 Pa at 220° C. and/or (ii) a loss modulus (G″) of not less than 20,000 Pa at 220° C.

The elastomer preferably contains a styrene group as a constitutional unit of a main chain. It is more preferable that the elastomer has a styrene group at each end of its main chain.

In this specification, the “constitutional unit” means a structure which is one of the units constituting the elastomer (polymer) and is derived from one monomer molecule.

In this specification, the “styrene unit” means, when styrene or a styrene derivative is polymerized to obtain a polymer, a constitutional unit derived from the styrene contained in the polymer. The “styrene unit” may have a substituted group. Examples of the substituted group include C1 to C5 alkyl group, C1 to C5 alkoxy group, C1 to C5 alkoxyalkyl group, acetoxy group, and carboxyl group.

The styrene group content of the elastomer is preferably not less than 10% by weight and not more than 65% by weight, and is more preferably not less than 20% by weight and not more than 50% by weight. The adhesive composition of the present invention containing such an elastomer further suitably suppresses warpage of a laminate when the laminate is subjected to a heating process.

Furthermore, the mass-average molecular weight of the elastomer is preferably not less than 20,000 and not more than 200,000, and is more preferably not less than 50,000 and not more than 150,000. The adhesive composition of the present invention containing such an elastomer more suitably suppresses warpage of a laminate when the laminate is subjected to a heating process.

Furthermore, the elastomer is preferably a block copolymer. Examples of the block copolymer include: polystyrene-poly(ethylene/propylene) block copolymers (SEP), styrene-isoprene-styrene block copolymers (SIS), styrene-butadiene-styrene block copolymers (SBS), styrene-butadiene-butylene-styrene block copolymers (SBBS), ethylene-propylene terpolymers (EPT), and hydrogenated versions of these block copolymers; styrene-ethylene-butylene-styrene block copolymers (SEBS), styrene-ethylene-propylene-styrene block copolymers (styrene-isoprene-styrene block copolymers) (SEPS), styrene-ethylene-ethylene-propylene-styrene block copolymers (SEEPS), styrene-ethylene-ethylene-propylene-styrene block copolymers (SeptonV9461 (manufactured by KURARAY CO., LTD.)) whose styrene block forms cross-linkage when reacted, SeptonV9475 (manufactured by KURARAY CO., LTD.), styrene-ethylene-butylene-styrene block copolymers (SeptonV9827 (manufactured by KURARAY CO., LTD.) having a reactive polystyrene hard block) whose styrene block forms cross-linkage when reacted, and polystyrene-poly(ethylene-ethylene/propylene) block-polystyrene block copolymers (SEEPS-OH: whose end is modified with a hydroxyl group). The elastomer preferably has a styrene group content and a mass-average molecular weight in the aforementioned ranges.

The block copolymer is preferably a diblock copolymer or a triblock copolymer, and is further preferably a triblock copolymer. A diblock copolymer and a triblock copolymer may be used in combination. In the present invention, an adhesive layer prepared from an adhesive composition containing a diblock copolymer, a triblock copolymer or a combination of a diblock copolymer and a triblock copolymer has a loss coefficient (tan σ) at 220° C. of 1.1 or below.

Note here that the loss coefficient is obtained by measuring, with a known dynamic viscoelasticity measuring instrument, a sample of the adhesive layer having a thickness of 1 mm and a diameter of 25 mm at a heating rate of 5° C. per minute from 50° C. to 250° C. with a shear condition of 10 Hz.

The block copolymer in accordance with the present invention may be bound to at least one functional group-containing group. Such a block copolymer can be obtained by causing, with use of a modifying agent, at least one functional group-containing group to bind with a known block copolymer.

The functional group-containing group is a group which contains one or more functional groups. Examples of the functional group contained in the functional group-containing group of the present invention include: amino group, acid anhydride groups (preferably, a maleic anhydride group), imide group, urethane group, epoxy group, imino group, hydroxyl group, carboxyl group, silanol group, and alkoxysilane group (alkoxy is preferably C1 to C6 alkoxy group). In the present invention, the elastomer is preferably a block copolymer and has a functional group which gives polarity. According to the present invention, when an adhesive composition contains a block copolymer that has at least one functional group-containing group, the adhesive composition has an improved flexibility and adhesion property.

The elastomer is preferably a hydrogenated elastomer. The hydrogenated elastomer has an improved stability against heat, and thus is less likely to suffer deterioration such as decomposition and polymerization. In addition, the hydrogenated elastomer has better solubility in a hydrocarbon solvent and a higher resistance to a resist solvent.

Moreover, of the aforementioned elastomers, it is preferable to use an elastomer that has styrene parts at both ends of its molecule. Since such an elastomer has as block structures highly heat-stable styrene parts at both ends of its molecule, the elastomer has a high heat resistance.

Moreover, the elastomer is more preferably a hydrogenated block copolymer which (i) is obtained by hydrogenating a block copolymer of styrene and conjugate diene and (ii) has styrene parts at both ends of its molecule. Such an elastomer is more heat-stable and thus is less likely to suffer deterioration such as decomposition and polymerization. In addition, the elastomer has better solubility in a hydrocarbon solvent and a higher resistance to a resist solvent. Furthermore, since the elastomer has highly heat-stable styrene parts (block structures) at both ends of its molecule, the elastomer has a higher heat resistance.

Examples of a commercially-available product which can be used as the elastomer above, which is a main component of the adhesive composition of the present invention, include “SEPTON (product name)” manufactured by KURARAY CO., LTD., “HYBRAR (product name)” manufactured by KURARAY CO., LTD., “Tuftec (product name)” manufactured by Asahi Kasei Corp., and “DYNARON (product name)” manufactured by JSR Corporation.

The adhesive composition of the present invention contains the elastomer in an amount of, for example, preferably not less than 10 parts by weight and not more than 80 parts by weight and is further preferably not less than 20 parts by weight and not more than 60 parts, relative to the total weight (100 parts by weight) of the adhesive composition.

Furthermore, a mixture of a plurality of types of elastomers may be used. That is, the adhesive composition of the present invention may contain a plurality of types of elastomers. Even in a case where the adhesive composition contains a plurality of types of elastomers, the adhesive composition is encompassed in the scope of the present invention provided that an adhesive layer prepared from the adhesive composition has (i) a storage modulus (G′) of not less than 20,000 Pa at a 220° C. and/or (ii) a loss modulus (G″) of not less than 20,000 Pa at 220° C.

In the case where the adhesive composition of the present invention is to contain a plurality of types of elastomers, the adhesive composition may be prepared such that the styrene group content of a mixture of the plurality of types of elastomers is in the aforementioned range. For example, in a case where an elastomer whose styrene group content is 10% by weight and an elastomer whose styrene group content is 60% by weight are mixed at a ratio of 1:1, an obtained elastomer has a styrene group content of 35% by weight. It is most preferable that the plurality of types of elastomers contained in the adhesive composition of the present invention each have (i) a styrene group content in the aforementioned range and (ii) a weight-average molecular weight in the aforementioned range.

(Hydrocarbon Resin)

The adhesive composition of the present invention may further contain a hydrocarbon resin. The hydrocarbon resin is a resin that has a hydrocarbon backbone and is obtained by polymerizing a monomer composition. An example of the hydrocarbon resin is a cycloolefin polymer.

Specific examples of the cycloolefin polymer include: ring-opened (co)polymers obtained by polymerizing a monomer component including a cycloolefin monomer; and resins obtained by addition (co)polymerization of a monomer component including a cycloolefin monomer.

Examples of the cycloolefin monomer include: bicylic compounds such as norbornene and norbornadiene; tricyclic compounds such as dicyclopentadiene and dihydropentadiene; tetracyclic compounds such as tetracyclododecene; pentacyclic compounds such as cyclopentadiene trimer: heptacyclic compounds such as tetracyclopentadiene; and alkyl(methyl, ethyl, propyl, butyl, etc.)-, alkenyl(vinyl etc.)-, alkylidene(ethylidene etc.)-, and aryl(phenyl, tolyl, naphthyl, etc.)-substituted versions of these polycyclic compounds. Of these, further preferable cycloolefin monomers are norbornene monomers selected from the group consisting of norbornene, tetracyclododecene, and alkyl-substituted versions of these monomers.

The hydrocarbon resin may further contain, as a monomer component, another monomer that is capable of being copolymerized with the above cycloolefin monomer. For example, the hydrocarbon resin preferably contains an alkene monomer. The alkene monomer is, for example, a C2 to C10 alkene monomer. Examples of the alkene monomer include α-olefin such as ethylene, propylene, 1-butene, isobutene, and 1-hexene. The alkene monomer may have a straight-chain structure or a blanched structure.

It is preferably that the hydrocarbon resin contains a cycloolefin monomer as a monomer component, in view of achieving a high heat resistance (i.e., the hydrocarbon resin is less likely to decompose by heat and less weight is lost from heat). The cycloolefin monomer is contained in an amount of preferably not less than 5 mol %, and more preferably not less than 10 mol %, and further preferably not less than 20 mol %, relative to the total weight of the monomer component constituting the hydrocarbon resin. Although there is no particular upper limit on the amount of the cycloolefin monomer relative to the amount of the entire monomer component constituting the hydrocarbon resin, the amount is preferably not more than 80 mol % and is more preferably not more than 70 mol %, in view of solubility and temporal stability of a solution of the hydrocarbon resin.

The hydrocarbon resin may further contain, as a monomer component, a straight-chain or branched alkene monomer. The alkene monomer is contained in an amount of preferably 10 mol % to 90 mol %, more preferably 20 mol % to 85 mol %, and further preferably 30 mol % to 80 mol % with respect to the entire monomer component constituting the hydrocarbon resin, in view of solubility and flexibility.

Note that, in order to reduce generation of gas at high temperatures, the hydrocarbon resin is preferably a resin which contains no polar group, such as a resin obtained by polymerizing a monomer component including a cycloolefin monomer and an alkene monomer.

How and in what condition the monomer component is polymerized are not particularly limited, and therefore can be appropriately determined in accordance with a standard method known in the art.

Examples of a commercially-available product that can be used as a hydrocarbon resin include “TOPAS” manufactured by POLYPLASTICS CO., LTD, “APEL” manufactured by Mitsui Chemicals, Inc., “ZEONOR” and “ZEONEX” manufactured by JAPAN ZEON CORPORATION, and “ARTON” manufactured by JSR Corporation.

The glass transition point (Tg) of the hydrocarbon resin is preferably not less than 60° C., and is particularly preferably not less than 70° C. When the hydrocarbon resin has a glass transition point of not less than 60° C., an adhesive layer prepared from the adhesive composition containing the hydrocarbon resin is less likely to soften even when a laminate is exposed to a high-temperature environment.

The amount of the hydrocarbon resin contained in the adhesive composition in accordance with the present invention is not limited, provided that an adhesive layer prepared from the adhesive composition has (i) a storage modulus (G′) of not less than 20,000 Pa at 220° C. and/or (ii) a loss modulus (G″) of not less than 20,000 Pa at 220° C. For example, assuming that the elastomer is contained in an amount of 100 parts by weight, the hydrocarbon resin is contained in an amount of preferably not less than 1 part by weight and not more than 50 parts by weight.

(Solvent)

A solvent (main solvent) contained in the adhesive composition of the present invention is not limited, provided that it is capable of dissolving elastomers. Examples of usable solvents include non-polar hydrocarbon solvents and polar/non-polar petroleum solvents.

The solvent more preferably contains a fused polycyclic hydrocarbon. When the solvent contains a fused polycyclic hydrocarbon, it is possible to prevent clouding of the adhesive composition when the adhesive composition is stored in the form of liquid (in particular, at low temperatures). This improves product stability.

The hydrocarbon solvent may be a straight-chain hydrocarbon, a branched hydrocarbon or a cyclic hydrocarbon. Examples of the hydrocarbon solvent include: C3 to C15 straight-chain hydrocarbons such as hexane, heptane, octane, nonane, decane, undecane, dodecane, and tridecane; C4 to C15 branched hydrocarbons such as methyl octane; and cyclic hydrocarbons such as p-mentane, o-mentane, m-mentane, diphenylmentane, 1,4-terpin, 1,8-terpin, bornane, nornornane, pinane, thujane, carane, longifolene, α-terpinene, β-terpinene, γ-terpinene, α-pinene, β-pinene, α-thujone, and β-thujone.

Examples of the petroleum solvents include cyclohexane, cycloheptane, cyclooctane, naphthalene, decahydronaphthalene (decalin), and tetrahydronaphthalene (tetralin).

The fused polycyclic hydrocarbon is a fused cyclic hydrocarbon in which two or more rings share only one side. It is preferable to use a hydrocarbon containing two rings fused together.

Examples of such a fused polycyclic hydrocarbon include: those composed of a five-membered ring and a six-membered ring; and those composed of two six-membered rings. Examples of fused polycyclic hydrocarbons composed of a five-membered ring and a six-membered ring include indene, pentalene, indane, and tetrahydroindene. Examples of fused polycyclic hydrocarbons composed of two six-membered rings include naphthalene, decahydronaphthalene, and tetrahydronaphthalene.

One of these solvents may be used solely or two or more of these solvents may be used in combination. In a case where the solvent contains a fused polycyclic hydrocarbon, the solvent may be composed only of the fused polycyclic hydrocarbon or may further contain another component such as a saturated aliphatic hydrocarbon. In the case where the solvent further contains another component, the fused polycyclic hydrocarbon is contained in an amount of preferably not less than 40% by weight, and is more preferably not less than 60% by weight, with respect to the total weight of the hydrocarbon solvent. When the fused polycyclic hydrocarbon is contained in an amount of not less than 40% by weight relative to the total weight of the hydrocarbon solvent, the foregoing resin is readily soluble in such a hydrocarbon. When the mixing proportions of the fused polycyclic hydrocarbon and the saturated aliphatic hydrocarbon are in the above range, it is possible to reduce odor of the fused polycyclic hydrocarbon.

Examples of the above saturated aliphatic hydrocarbon include: C3 to C15 straight-chain hydrocarbons such as hexane, heptane, octane, nonane, decane, undecane, dodecane, and tridecane; C4 to C15 branched hydrocarbons such as methyl octane; and p-mentane, o-mentane, m-mentane, diphenylmentane, 1,4-terpin, 1,8-terpin, bornane, nornornane, pinane, thujane, carane, and longifolene.

Note that the amount of the solvent contained in the adhesive composition of the present invention may be determined appropriately according to a desired thickness of an adhesive layer to be prepared from the adhesive composition. For example, assuming the total amount of the adhesive composition is 100 parts by weight, the solvent is contained in an amount of preferably not less than 20 parts by weight and not more than 90 parts by weight. When the amount of the solvent is in the range above, it is easy to control viscosity.

(Thermal Polymerization Inhibitor)

The adhesive composition in accordance with the present invention may contain a thermal polymerization inhibitor as needed. The thermal polymerization inhibitor has the function of preventing a heat-induced radical polymerization reaction. Specifically, the thermal polymerization inhibitor is highly reactive with radicals, and thus reacts with the radicals before monomers do and thereby inhibits the monomers from being polymerized with the radicals. The adhesive composition, which contains the thermal polymerization inhibitor, inhibits polymerization under a high-temperature environment (in particular, at 250° C. to 350° C.).

For example, in a semiconductor production process, there is a high-temperature process in which a wafer having a support plate (support) bonded thereto is heated at 250° C. for one hour. If polymerization of the adhesive composition is induced by heat in this process, the adhesive composition becomes less soluble in a stripping solution when the support plate is to be separated from the wafer after the high-temperature process. As a result, the support plate cannot be separated from the wafer very well. However, when the adhesive composition contains a thermal polymerization inhibitor, heat-induced oxidization and its associated polymerization reaction are suppressed. Therefore, it is possible to easily separate the support plate from the wafer and suppress a residue of the adhesive layer even in the case where the high-temperature process is carried out.

The thermal polymerization inhibitor is not particularly limited, provided that it has the function of inhibiting a heat-induced radical polymerization reaction. However, a thermal polymerization inhibitor having a phenol structure is preferable. The adhesive composition containing such a thermal polymerization inhibitor keeps a good solubility even after being subjected to the high-temperature process in the air. The thermal polymerization inhibitor having a phenol structure is, for example, a hindered phenol antioxidant. Examples of the hindered phenol antioxidant include: pyrogallol, benzoquinone, hydroquinone, methylene blue, tert-butylcatechol, monobenzyl ether, methyl hydroquinone, amylquinone, amyloxyhydroquinone, n-butylphenol, phenol, hydroquinone monopropyl ether, 4,4′-(1-methylethylidene)bis(2-methylphenol), 4,4′-(1-methylethylidene)bis(2,6-dimethylphenol), 4,4′-[1-[4-(1-(4-hydroxyphenyl)-1-methylethyl)phenyl]ethylidene]bisphenol, 4,4′,4″-ethylidenetris(2-methylphenol), 4,4′,4″-ethylidenetrisphenol, 1,1,3-tris(2,5-dimethyl-4-hydroxyphenyl)-3-phenylpropane, 2,6-di-tert-butyl-4-methylphenol, 2,2′-methylenebis(4-methyl-6-tert-butylphenol), 4,4′-butylidenebis(3-methyl-6-tert-butylphenol), 4,4′-thiobis(3-methyl-6-tert-butylphenol), 3,9-bis[2-(3-(3-tert-butyl-4-hydroxy-5-methylphenyl)-propionyloxy)-1,1-dimethylethyl]-2,4,8,10-tetraoxaspiro(5,5)undecane, triethyleneglycol-bis-3-(3-tert-butyl-4-hydroxy-5-methylphenyl) propionate, n-octyl-3-(3,5-di-tert-butyl-4-hydroxyphenyl)propionate, pentaerythryltetrakis[3-(3,5-di-tert-butyl-4-hydroxyphenyl)propionate] (product name: IRGANOX1010 manufactured by BASF Corporation), tris(3,5-di-tert-butylhydroxybenzil) isocyanurate, and thiodiethylenebis[3-(3,5-di-tert-butyl-4-hydroxyphenyl) propionate]. One of these thermal polymerization inhibitors may be used solely or two or more thermal polymerization inhibitors may be used in combination.

The amount of the thermal polymerization inhibitor to be contained may be appropriately determined according to the type of the elastomer and purpose and use environment of the adhesive composition. Note however that, for example, assuming the amount of the elastomer is 100 parts by weight, the thermal polymerization inhibitor is contained in an amount of preferably not less than 0.1 parts by weight and not more than 10 parts by weight. When the thermal polymerization inhibitor content is in the range above, the thermal polymerization inhibitor well performs its function of preventing a heat-induced radical polymerization reaction. This makes it possible to even more suppress a decrease in the solubility of the adhesive composition in a stripping solution after the high-temperature process.

Moreover, the adhesive composition of the present invention may contain, according to need, an entrainer that (i) has a different composition from the solvent (main solvent) for dissolving the elastomer and (ii) dissolves the thermal polymerization inhibitor. The entrainer is not particularly limited. An organic solvent which dissolves components contained in the adhesive composition can be used as the entrainer.

The organic solvent is not limited provided that it dissolves the components contained in the adhesive composition so that a homogeneous solution is obtained. Any one organic solvent may be used solely or two or more organic solvents may be used in combination.

The organic solvent is, for example, a terpene solvent containing as a polar group an oxygen atom, a carbonyl group, or an acetoxy group. Specific examples of the organic solvent include: geraniol, nerol, linalool, citral, citronellol, menthol, isomenthol, neomenthol, α-terpeneol, β-terpeneol, γ-terpeneol, terpinene-1-ol, terpinene-4-ol, dihydroterpinyl acetate, 1,4-cineol, 1,8-cineol, borneol, carvone, ionone, thujone, and camphor. The examples also include: lactones such as γ-butyrolactone; ketones such as acetone, methyl ethyl ketone, cyclohexanone (CH), methyl-n-pentylketone, methyl isopentyl ketone, and 2-heptanone; polyhydric alcohols such as ethylene glycol, diethylene glycol, propylene glycol, and dipropylene glycol; ester bond-containing compounds such as ethylene glycol monoacetate, diethylene glycol monoacetate, propylene glycol monoacetate, and dipropylene glycol monoacetate; monoalkyl ethers of the above polyhydric alcohols or the ester bond-containing compounds such as monomethyl ether, monoethyl ether, monopropyl ether, and monobutyl ether; and derivatives derived from polyhydric alcohols of ether bond-containing compounds etc. such as monophenyl ether (especially preferred are propylene glycol monomethyl ether acetate (PGMEA) and propylene glycol monomethyl ether (PGME)); cyclic ethers such as dioxane, and esters such as methyl lactate, ethyl lactate (EL), methyl acetate, ethyl acetate, butyl acetate, methyl pyruvate, ethyl pyruvate, methyl methoxy propionate, and ethyl ethoxy propionate; and aromatic organic solvents such as anisole, ethyl benzil ether, cresyl methyl ether, diphenyl ether, dibenzil ether, phenetole, and butyl phenyl ether.

The amount of the entrainer may be appropriately determined according to the type of the thermal polymerization inhibitor or the like. For example, assuming that the amount of the thermal polymerization inhibitor is 1 part by weight, the entrainer is contained in an amount of preferably not less than 1 part by weight and not more than 50 parts by weight, further preferably 1 to 30 parts by weight, and most preferably 1 to 15 parts by weight. When the entrainer content is in the ranges above, the thermal polymerization inhibitor dissolves thoroughly.

(Other Components)

The adhesive composition of the present invention may further contain another component that has miscibility with the components contained in the adhesive composition, provided that essential properties of the adhesive composition of the present invention are maintained. Examples of another component include commonly-used additives such as additional resins, plasticizers, adhesive adjuvants, stabilizers, coloring agents and surfactants.

(Method for Preparing Adhesive Composition)

A method for preparing the adhesive composition of the present invention is not particularly limited, and a well-known method can be used. For example, the adhesive composition of the present invention can be obtained by (i) dissolving an elastomer in a solvent and (ii) stirring constituents with use of a known stirrer.

In a case where the adhesive composition of the present invention contains a thermal polymerization inhibitor, it is preferable to (i) dissolve the thermal polymerization inhibitor in an entrainer in advance to obtain a mixture and then (ii) add the mixture to a main solvent in which an elastomer is dissolved.

[Use of Adhesive Composition of the Present Invention]

The adhesive composition of the present invention is used to bond a wafer and a support to thereby form a laminate.

The support is, for example, a member which supports the wafer in a process of thinning the wafer, and is bonded to the wafer with use of the adhesive composition of the present invention. In one embodiment, for example, the support is made of glass or silicon having a film thickness in a range of 500 μm to 1000 μm.

Note that, in one embodiment, the support has a hole(s) passing therethrough in a thickness direction. By pouring a solvent that dissolves the adhesive composition into a gap between the support and the wafer via the hole(s), it is possible to easily separate the support from a substrate (the wafer).

In another embodiment, there may be provided a reactive layer between the support and the wafer in addition to the adhesive layer. The reactive layer changes its property upon absorbing light coming through the support. This makes it possible to easily separate the support and the wafer by irradiating the reactive layer with light etc. so as to change the property of the reactive layer. In this case, it is preferable to use a support that does not have a hole(s) passing therethrough in the thickness direction.

Light for irradiation of the reactive layer may be appropriately selected according to a wavelength that the reactive layer absorbs. Examples of the light include (i) laser beams produced by (a) solid-state lasers such as a YAG laser, a ruby laser, a glass laser, a YVO₄ laser, an LD laser, and a fiber laser, (b) liquid lasers such as a dye laser, (c) gas lasers such as a CO₂ laser, an excimer laser, an Ar laser, and a He—Ne laser, (d) semiconductor lasers, and (e) free electron lasers and (ii) light other than laser beams. The wavelength of light that the reactive layer absorbs may be, but is not limited to, not more than 600 nm, for example.

The reactive layer may contain a light-absorbing agent which is decomposed by light etc. Examples of the light-absorbing agent include: fine-particle metal powder such as graphite powder, iron, aluminum, copper, nickel, cobalt, manganese, chrome, zinc, and tellurium; metal-oxide powder such as black oxide of titanium; carbon black; and dyes and pigments such as aromatic diamino metal complexes, aliphatic diamine metal complexes, aromatic dithiol metal complexes, mercapto phenol metal complexes, squarylium compounds, cyanine pigments, methine pigments, naphthoquinone pigments, and anthraquinone pigments. Such a reactive layer can be formed by, for example, mixing a material for the reactive layer with a binder resin and applying the mixture to the support. The light-absorbing agent may be a resin containing a light-absorbing group.

The reactive layer may be an inorganic film or an organic film formed by a plasma CVD method. The inorganic film is, for example, a metal film. The organic film is, for example, a fluorocarbon film. Such a reactive layer can be formed on the support by a plasma CVD method, for example.

The adhesive composition of the present invention is suitably used to bond a wafer and a support together, which wafer is to be subjected to a thinning process after being bonded to the support. As described earlier, the support keeps the strength of the wafer when the wafer is thinned. The adhesive composition of the present invention is suitably used to bond a wafer and a support in this manner.

Since the adhesive composition of the present invention is excellent in heat resistance, it is used to bond the wafer and the support together. The wafer is preferably a wafer that is to be subjected to an environment of not less than 150° C. after being bonded to the support. The wafer is more preferably a wafer that is to be subjected to an environment of not less than 180° C. after being bonded to the support, and further preferably a wafer that is to be subjected to an environment of not less than 220° C. after being bonded to the support.

For example, in the case of forming a through-hole electrode etc. on a wafer, the wafer and a support that is bonded to the wafer, i.e., a laminate, are subjected to an environment of 150° C. or higher. Even after being subjected to such an environment, the wafer and the support, which are bonded together with the adhesive composition of the present invention, are easily separated because the adhesive layer prepared from the adhesive composition of the present invention readily dissolves in a solvent. Note that, since the adhesive composition of the present invention contains an elastomer having a styrene content and a weight-average molecular weight in the aforementioned ranges, it is possible to suppress membrane stress even when the adhesive layer is heated, and thus possible to suppress the warpage of the laminate.

Note that a method for thinning a wafer of the laminate and a method for heating the laminate at 150° C. or higher are also encompassed in the scope of the present invention.

[Removal of Adhesive Layer Prepared from Adhesive Composition]

In the case of (i) separating the wafer and the support bonded together with the adhesive composition of the present invention by, for example, changing the property of the reactive layer and thereafter (ii) removing the adhesive layer, the adhesive layer can be easily dissolved and removed by using the foregoing solvent. Alternatively, in a case where the wafer and the support are bonded together via the adhesive layer without the above reactive layer etc., the wafer and the support can be separated by directly supplying the solvent to the adhesive layer to thereby readily dissolve and remove the adhesive layer. In this case, it is more preferable that the support has a through-hole(s) in order to efficiently supply the solvent to the adhesive layer.

[Film Adhesive]

The adhesive composition of the present invention can be used in various ways according to purposes. For example, (i) the adhesive composition in the form of liquid may be directly applied as appropriate, by a known method, to a wafer or a support (a subject to be processed) so that a resulting adhesive layer will have a desired thickness and (ii) the adhesive composition may be dried to form the adhesive layer. Alternatively, (a) the adhesive composition may be applied to a film such as a flexible film and then dried to form an adhesive layer, thereby obtaining a film adhesive and thereafter (b) the film adhesive may be attached to a wafer or a support (a subject to be processed).

As described above, a film adhesive in accordance with the present invention includes: a film; and an adhesive layer which contains the adhesive composition of the present invention and is formed on the film.

The film adhesive can further include a protective film which covers the adhesive layer. In this case, the adhesive layer can be easily provided on a subject to be processed, by (i) peeling off the protective film from one surface of the adhesive layer so that the adhesive layer is exposed, (ii) placing, on the subject to be processed, the adhesive layer thus exposed and then (iii) peeling off the film from the other surface of the adhesive layer.

Such a film adhesive makes it possible to form an adhesive layer that has a more uniform film thickness and a flat and smooth surface, in comparison with a case where an adhesive layer is formed by directly applying an adhesive composition to a subject to be processed.

The film, which is part of the film adhesive, is not particularly limited provided that it has a releasing property so that the adhesive layer formed on the film can be peeled off from the film and adhered (transferred) to the wafer or the support. Note, however, that the film is preferably a flexible film. The flexible film is, for example, a synthetic resin film that has a film thickness in a range of 15 μm to 125 μm and is made of polyethylene terephthalate, polyethylene, polypropylene, polycarbonate, polyvinyl chloride and/or the like. It is preferable that the film has been subjected to release process as needed so that the adhesive layer is easily transferred to the wafer or the support.

The film adhesive is obtained by, for example, (i) applying the adhesive composition of the present invention to the film as appropriate by a known method so that a resulting adhesive layer will have a desired thickness (e.g., 10 μm to 1000 μm) after being dried and (ii) drying the adhesive composition.

In the case of using the protective film, the protective film is not limited provided that it is capable of being peeled off from the adhesive layer. For example, the protective film is preferably a polyethylene terephthalate film, a polypropylene film or a polyethylene film. Furthermore, the protective film is preferably coated with silicon or baked silicon. This makes it easy to peel off the protective film from the adhesive layer. The film thickness of the protective film is not particularly limited, but the film thickness is preferably in a range of 15 μm to 125 μm. This makes it possible to ensure that the film adhesive including the protective film has flexibility.

How to use the film adhesive is not particularly limited. For example, in the case where the film adhesive includes the protective film, the film adhesive can be used in the following manner: the protective film is peeled off so that the adhesive layer is exposed; the adhesive layer thus exposed is placed on a subject to be processed; and a heating roller is rolled against a surface of the film (opposite side of the adhesive layer), whereby the adhesive layer is thermally compressed to a surface of the subject to be processed. In this case, the protective film peeled off from the film adhesive may be rolled up by a roller such as a reel roller so as to be stored and reused.

[Bonding Method]

A bonding method in accordance with the present invention includes the step of bonding a support to a wafer with the use of the adhesive composition of the present invention. When the wafer and the support are bonded together with the use of the adhesive composition of the present invention to form a laminate, the laminate is less likely to warp even when heated.

In the step of bonding, the support may be bonded to the wafer via an adhesive layer that is prepared in advance from the adhesive composition of the present invention. The adhesive layer can be formed by, for example, applying the adhesive composition to the wafer and baking the adhesive composition. The temperature at which the adhesive composition is baked and the time during which the adhesive composition is baked etc. can be appropriately selected according to the adhesive composition etc. to be used.

Alternatively, in the step of bonding, the support can be bonded to the wafer by carrying out heating and pressure application under reduced pressure. The temperature, time, and pressure for bonding the support to the wafer can be appropriately selected according to, for example, the adhesive composition to be used. For example the temperature for bonding is in a range of 50° C. to 250° C., and preferably 100° C. to 250° C. The time for bonding is in a range of 10 seconds to 15 minutes, and preferably 30 seconds to 10 minutes. The pressure for bonding is in a range of 100 kg to 10,000 kg, and preferably 1,000 kg to 10,000 kg. Furthermore, in the step of bonding, the wafer and the support can be bonded together under reduced pressure (e.g. at not more than 1 Pa).

The following description will discuss embodiments of the present invention in more detail, with Examples. It is needless to say that the present invention is not limited to the following Examples, and details can be altered in various ways. Furthermore, the present invention is not limited to the description of the embodiments above, but may be altered in various ways by a skilled person within the scope of the claims. Any embodiment based on a proper combination of technical means disclosed in different embodiments is also encompassed in the technical scope of the present invention. Moreover, the literature cited in this specification is of assistance as reference in this specification.

### Examples

[Preparation of Adhesive Composition]

The following Tables 4 to 7 show elastomers (hydrocarbon resins), thermal polymerization inhibitors, main solvents, and entrainers which were used in Examples 1 through 14 and Comparative Examples 1 through 3. Note that, in Tables 4 to 7, the unit “part(s)” represents “part(s) by weight”.

The elastomers used in Examples 1 through 14 are as follows: Septon (product name) manufactured by Kuraray Co., Ltd., including Septon 8004 (SEP: polystyrene-poly(ethylene/propylene) block), Septon 4055 (SEEPS: polystyrene-poly(ethylene-ethylene/propylene) block-polystyrene), Septon 4033 (SEPS: polystyrene-poly(ethylene/propylene block-polystyrene), SeptonV9827 (SEBS: styrene-ethylene-butylene-styrene block copolymer whose styrene block forms cross-linkage when reacted), Septon 2002 (SEPS: styrene-isoprene-styrene block), and SeptonHG252 (SEEPS-OH: polystyrene-poly(ethylene-ethylene/propylene) block-polystyrene whose end is modified with a hydroxyl group); Tuftec (product name) H1051 (SEBS, hydrogenated styrene thermoplasticity elastomer) manufactured by Asahi Kasei Corp.; and A1 (a copolymer containing styrene, 1-adamantyl methacrylate and stearyl methacrylate in a ratio of 20:60:20 (ratio by weight). In Examples 4 through 7, the following hydrocarbon resins were mixed with the elastomers at a mixing ratio shown in Tables 4 and 5: APEL (product name) manufactured by Mitsui Chemicals, Inc., including APEL8008T (cycloolefin copolymer; ethylene-tetracyclododecene copolymer, Mw=100,000, Mw/Mn=2.1, ethylene:cyclododecene=80:20 (molar ratio)), APEL5015 (cycloolefin copolymer; ethylene-tetracyclododecene copolymer, Mw=70,000, Mw/Mn=2.0, ethylene:cyclododecene=55:45 (molar ratio)), and APEL6013T (cycloolefin copolymer; etyrene-tetracyclododecene copolymer, Mw=90,000, Mw/Mn=2.0, ethylene:cyclododecene=65:35 (molar ratio); and TOPAS (product name) TM (cyloolefin copolymer; ethylene-norbornene copolymer, Mw=10,000, Mw/Mn=2.08, norbornene:ethylene=50:50 (ratio by weight) manufactured by POLYPLASTICS CO., LTD. Note that the “hydrogenated” in the examples means a polymer obtained For convenience of description, the “elastomer” in the following descriptions refers to an elastomer alone or a mixture of an elastomer and a hydrocarbon resin.

The elastomers (hydrocarbon resins) used in Comparative Examples 1 through 3 are: TOPAS (product name) 8007 (cycloolefin copolymer; ethylene-norbornene copolymer, Mw=100,000, Mw/Mn=1.9, norbornene:ethylene=65:35 (ratio by weight)) manufactured by POLYPLASTICS CO., LTD; APEL (product name) 8008T manufactured by Mitsui Chemicals, Inc.; and Septon (product name) 2063 (SEPS, hydrogenated styrene thermoplastic elastomer) manufactured by KURARAY CO., LTD, respectively.

The following Tables 1 and 2 show the styrene content and weight-average molecular weight of each of the elastomers, and Table 3 shows the weight-average molecular weight of each of the hydrocarbon resins. The weight-average molecular weight was measured by GPC (Gel Permeation Chromatography). The styrene contents are those stated in instructions attached to the commercial products.

TABLE 1

| | SeptonHG252 | Septon8004 | Septon4033 | Septon4055 | TuftecH1051 | Septon2063 |
|---|---|---|---|---|---|---|
| Styrene Group Content | 28 | 31 | 30 | 30 | 42 | 12 |
| Mw | 67,000 | 98,000 | 90,000 | 330,000 | 78,000 | 95,000 |

TABLE 2

| | SeptonV9827 | Septon2002 | A1 |
|---|---|---|---|
| Styrene Group Content | 30 | 30 | 20 |
| Mw | 90,000 | 54,000 | 10,000 |

TABLE 3

| | | | | TOPAS | |
|---|---|---|---|---|---|
| | APEL5015 | APEL6013T | APEL8008T | TM | TOPAS8007 |
| Mw | 70,000 | 90,000 | 100,000 | 10,000 | 100,000 |

The thermal polymerization inhibitor used here is IRGANOX1010 (product name) 1010 manufactured by BASF Corporation. The main solvent used here is decahydro naphthalene represented by the following chemical formula (I). The entrainer used here is butyl acetate.

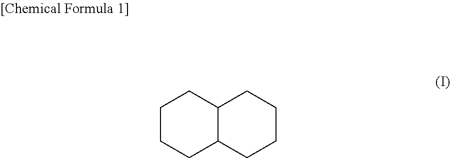

An adhesive composition of Example 1 was prepared in the following manner. First, Septon8004 (hydrogenated styrene elastomer) was dissolved in a main solvent so that a resulting mixture would have a concentration of 25% by weight. Next, a thermal polymerization inhibitor was added to the mixture in an amount of 1 parts by weight with respect to 100 parts by weight of the elastomer, and an entrainer was added to the mixture in an amount of 15 parts by weight with respect to 100 parts by weight of the elastomer. In this way, the adhesive composition was obtained. Also in Examples 2 to 14 and Comparative Examples 1 to 3, the similar process was performed to obtain adhesive compositions.

[Viscoelasticity Measurement]

The adhesive compositions of Examples 1 through 14 and Comparative Examples 1 through 3 were measured for their storage modulus (G′) and loss modulus (G″) at 220° C. with a dynamic viscoelasticity measuring instrument. First, a prepared adhesive composition was applied to a polyethylene film on which a release agent had been applied, and then was baked in an oven under atmospheric pressure at 100° C. for 60 minutes and 180° C. for 60 minutes to obtain an adhesive layer (thickness: 0.5 mm). The adhesive layer was separated from the polyethylene film, and measured for its storage modulus (G′) and loss modulus (G″) with a dynamic viscoelasticity measuring instrument (VAR100 manufactured by Fischer). The storage modulus (G′) and the loss modulus (G″) at 220° C. were measured under the following conditions: a sample of the adhesive layer had a thickness of 1 mm and a diameter of 25 mm, a parallel plate having a diameter of 25 mm was used, and the sample was heated from 50° C. to 250° C. at a heating rate of 5° C. per minute with a shear condition of 10 Hz. As shown in Tables 4 through 6, the storage modulus (G′) and the loss modulus (G″) at 220° C. were each 20,000 Pa or greater in Examples 1 through 14. On the other hand, as shown in Table 7, the storage modulus (G′) and the loss modulus (G″) at 220° C. were each less than 20,000 Pa in Comparative Examples 1 through 3.

[Formation of Adhesive Layer]

The adhesive composition was applied to a semiconductor wafer substrate (12 inches, made of silicon) by spin coating so that the adhesive composition would have a film thickness of 50 nm. Then, the adhesive composition was baked at 100° C., 160° C., and 220° C. each for 5 minutes. In this way, an adhesive layer was obtained.

[Bonding]

A wafer and a bare glass support (12 inches) having a reactive layer thereon were bonded together at 215° C. for 5 minutes in vacuum with a pressing strength of 4000 kg to obtain a laminate. The reactive layer absorbs laser beams having a wavelength of 532 nm. Meanwhile, it was confirmed that there was no bonding failure (i.e., there was no portion where the glass support and the wafer are not properly bonded) in a thinning process and a heating process after the bonding process, which failure may result in a damage on the wafer or a decrease in in-plane uniformity of the wafer.

Next, a back surface of the wafer was subjected to a thinning (50 nm) treatment with a backgrinding device manufactured by DISCO Corporation, and was heated at 220° C. for 3 hours in a nitrogen environment. It was confirmed that the laminate had a sufficient heat resistance. Moreover, the amount of warpage of the laminate was measured with a laser displacement meter (model: LK-G30) manufactured by KEYENCE Corporation. As a result, it was found that the amount of warpage of the laminate in Example 1 was 200 μm.

Next, the following will describe a method for measuring the amount of warpage of the laminate. The height in a thickness direction was measured at various positions on the upper surface of the wafer with use of the laser displacement meter. Then, the height of the wafer in the thickness direction of the laminate measured in the center of the wafer was subtracted from the height of the wafer in the thickness direction of the laminate measured at an end of the wafer. In this way, the amount of warpage was obtained.

[Separation]

The wafer was irradiated with laser of 532 nm through the glass support, whereby the glass support was separated from the wafer. The wafer from which the glass support was removed was subjected to spin cleansing with p-mentane, whereby the adhesive layer was removed from the wafer without leaving any residual. Tables 4 through 6 show the results of Examples 1 through 14. Table 7 shows the results of Comparative Examples 1 through 3.

TABLE 4

| | Example 1 | Example 2 | Example 3 | Example 4 |
|---|---|---|---|---|
| Elastomer | Septon8004 | Septon8004 | Septon8004 | Septon8004 |
| (Hydrocarbon | (100%) | (95%) | (90%) | (80%) |
| Resin) | | Septon4055 | Septon4055 | APEL8008T |
| | | (5%) | (10%) | (20%) |
| Additive | IRGANOX1010 | IRGANOX1010 | IRGANOX1010 | IRGANOX1010 |
| (Polymerization | 1 part | 1 part | 1 part | 1 part |
| Inhibitor) | | | | |
| Main Solvent | Decahydro | Decahydro | Decahydro | Decahydro |
| | naphthalene | naphthalene | naphthalene | naphthalene |
| Entrainer | Butyl Acetate | Butyl Acetate | Butyl Acetate | Butyl Acetate |
| | 15 parts | 15 parts | 15 parts | 15 parts |
| Storage Modulus | 230,000 | 351,000 | 470,000 | 180,000 |
| (220° C.) | | | | |
| G′(Pa) | | | | |
| Loss Modulus | 111,000 | 145,000 | 250,000 | 70,000 |
| (220° C.) | | | | |
| G″ (Pa) | | | | |
| Film Formation Property | Good | Good | Good | Good |
| Heat Resistance | Good | Good | Good | Good |
| Warpage | 200 | 100 | 50 | 200 |

TABLE 5

| | Example 5 | Example 6 | Example 7 | Example 8 | Example 9 |
|---|---|---|---|---|---|
| Elastomer | Septon8004 | Septon8004 | Septon8004 | Septon4033 | TuftecH1051 |
| (Hydrocarbon | (80%) | (80%) | (80%) | (100%) | (100%) |
| Resin) | APEL5015 | APEL6013T | TOPAS TM | | |
| | (20%) | (20%) | (20%) | | |
| Additive | IRGANOX1010 | IRGANOX1010 | IRGANOX1010 | IRGANOX1010 | IRGANOX1010 |
| (Polymerization | 1 part | 1 part | 1 part | 1 part | 1 part |
| Inhibitor) | | | | | |
| Main Solvent | Decahydro | Decahydro | Decahydro | Decahydro | Decahydro |
| | naphthalene | naphthalene | naphthalene | naphthalene | naphthalene |
| Entrainer | Butyl Acetate | Butyl Acetate | Butyl Acetate | Butyl Acetate | Butyl Acetate |
| | 15 parts | 15 parts | 15 parts | 15 parts | 15 parts |
| Storage Modulus | 180,000 | 180,000 | 170,000 | 120,000 | 120,000 |
| (220° C.) | | | | | |
| G′ (Pa) | | | | | |
| Loss Modulus | 70,000 | 70,000 | 68,000 | 110,000 | 42,000 |
| (220° C.) | | | | | |
| G″(Pa) | | | | | |
| Film Formation Property | Good | Good | Good | Good | Good |
| Heat Resistance | Good | Good | Good | Good | Good |
| Warpage | 200 | 200 | 200 | 150 | 150 |

TABLE 6

| | Example 10 | Example 11 | Example 12 | Example 13 | Example 14 |
|---|---|---|---|---|---|
| Elastomer | SeptonHG252 | SeptonV9827 | SeptonV9827 | SeptonV9827 | SeptonV9827 |
| (Hydrocarbon | (100%) | (100%) | (80%) | (80%) | (90%) |
| Resin) | | | Septon2002 | TOPAS TM | A1 |
| | | | (20%) | (20%) | (10%) |
| Additive | IRGANOX1010 | IRGANOX1010 | IRGANOX1010 | IRGANOX1010 | IRGANOX1010 |
| (Polymerization | 1 part | 1 part | 1 part | 1 part | 1 part |
| Inhibitor) | | | | | |
| Main Solvent | Decahydro | Decahydro | Decahydro | Decahydro | Decahydro |
| | naphthalene | naphthalene | naphthalene | naphthalene | naphthalene |
| Entrainer | Butyl Acetate | Butyl Acetate | Butyl Acetate | Butyl Acetate | Butyl Acetate |
| | 15 parts | 15 parts | 15 parts | 15 parts | 15 parts |
| Storage Modulus | 15,000 | 270,000 | 140,000 | 120,000 | 180,000 |
| (220° C.) | | | | | |
| G′(Pa) | | | | | |
| Loss Modulus | 22,000 | 200,000 | 110,000 | 100,000 | 130,000 |
| (220° C.) | | | | | |
| G″(Pa) | | | | | |
| Film Formation Property | Good | Good | Good | Good | Good |
| Heat Resistance | Good | Good | Good | Good | Good |
| Warpage | 200 | 200 | 200 | 200 | 200 |

TABLE 7

| | Comparative | Comparative | Comparative |
|---|---|---|---|
| | Example 1 | Example 2 | Example 3 |
| Elastomer | TOPAS8007 | APEL8008T | Septon2063 |
| (Hydrocarbon | (100%) | (100%) | (100%) |
| Resin) | | | |
| Additive | IRGANOX1010 | IRGANOX1010 | IRGANOX1010 |
| (Polymer- | 1 part | 1 part | 1 part |
| ization | | | |
| Inhibitor) | | | |
| Main Solvent | Decahydro | Decahydro | Decahydro |
| | naphthalene | naphthalene | naphthalene |
| Entrainer | Butyl Acetate | Butyl Acetate | Butyl Acetate |
| | 15 parts | 15 parts | 15 parts |
| Storage | 1,430 | 2,600 | 1,100 |
| Modulus | | | |
| (220° C.) | | | |
| G′(Pa) | | | |
| Loss Modulus | 7,600 | 11,000 | 3,200 |
| (220° C.) | | | |
| G″(Pa) | | | |
| Film Formation | Good | Good | Good |
| Property | | | |
| Heat | Good | Good | Good |
| Resistance | | | |
| Warpage | 440 | 400 | 500 |

As shown in Tables 4 to 6, the amounts of warpage of the laminates made with the use of the adhesive compositions of Examples 1 through 14 were smaller than those of Comparative Examples 1 through 3. More specifically, each of the amounts of warpage of the laminates made with the use of the adhesive compositions in Examples 1 through 14 was not more than 200 μm, which was equal to or less than half of each of the amounts of warpage of the laminates of Comparative Examples 1 through 3.

The results above showed that an adhesive composition, from which an adhesive layer is made which has a storage modulus (G′) of not less than 20,000 Pa at 220° C. and a loss modulus (G″) of not less than 20,000 Pa at 220° C., suppresses the amount of warpage of a laminate in comparison with an adhesive composition from which an adhesive layer is made which has a storage modulus (G′) of less than 20,000 Pa at 220° C. and a loss modulus (G″) less than 20,000 Pa at 220° C.

### INDUSTRIAL APPLICABILITY

An adhesive composition and a film adhesive in accordance with the present invention are suitably applicable to, for example, a process of producing a miniaturized semiconductor device.

What is claimed is:

1. An adhesive composition comprising an elastomer as a main component, wherein an adhesive layer prepared from said adhesive composition has a storage modulus (G′) of not less than 20,000 Pa at 220° C. and/or a loss modulus (G″) of not less than 20,000 Pa at 220° C.

2. The adhesive composition of claim 1, wherein the elastomer contains a styrene group.

3. The adhesive composition of claim 2, wherein the elastomer has the styrene group at each end of its main chain.

4. The adhesive composition of claim 2, wherein a styrene group content of the elastomer is not less than 10% by weight and not more than 65% by weight.

5. The adhesive composition of claim 1, wherein a mass-average molecular weight of the elastomer is not less than 50,000 and not more than 150,000.

6. The adhesive composition of claim 1, wherein the elastomer is a hydrogenated elastomer.

7. The adhesive composition of claim 1, wherein the elastomer is a block copolymer.

8. The adhesive composition of claim 1, wherein said adhesive composition is used to bond a wafer and a support, wherein the wafer is a wafer that is to be subjected to an environment of not less than 220° C. after being bonded to the support.

9. A film adhesive comprising:
a film; and
an adhesive layer provided on the film, wherein the adhesive layer contains the adhesive composition of claim 1.

10. A bonding method, comprising bonding a support to a wafer using the adhesive composition of claim 1.

11. The adhesive composition of claim 1, wherein (i) the storage modulus (G′) of the adhesive layer is not more than 500,000 and/or (ii) the loss modulus (G″) of the adhesive layer is not more than 500,000.

12. The adhesive composition of claim 1, wherein the elastomer (i) has a styrene group at each end of its main chain and (ii) is a hydrogenated elastomer.

13. The adhesive composition of claim 12, wherein the elastomer is a block copolymer.

14. The adhesive composition of claim 12, wherein a styrene group content of the elastomer is not less than 20% by weight and not more than 50% by weight.

15. The adhesive composition of claim 13, wherein the block copolymer is a block copolymer of styrene and conjugated diene.

16. The adhesive composition of claim 13, wherein the block copolymer is a diblock copolymer or a triblock copolymer.

17. The adhesive composition of claim 13, wherein the block copolymer is bound to at least one functional group-containing group which is a group containing one or more functional groups.

18. The adhesive composition of claim 17, wherein the one or more functional groups contained in the functional group-containing group are an amino group, an acid anhydride group, an imide group, an urethane group, an epoxy group, an imino group, a hydroxyl group, a carboxyl group, a silanol group, and/or an alkoxysilane group.

19. The adhesive composition of claim 1, further comprising a thermal polymerization inhibitor for preventing a heat-induced radical polymerization reaction.

20. The adhesive composition of claim 1, wherein the elastomer is at least one copolymer selected from the group consisting of polystyrene-poly(ethylene/propylene) block copolymers (SEP), styrene-isoprene-styrene block copolymers (SIS), styrene-butadiene-styrene block copolymers (SBS), styrene-butadiene-butylene-styrene block copolymers (SBBS), ethylene-propylene terpolymers (EPT), and hydrogenated versions of these block copolymers; styrene-ethylene-butylene-styrene block copolymers (SEBS), styrene-ethylene-propylene-styrene block copolymers (styrene-isoprene-styrene block copolymers) (SEPS), styrene-ethylene-ethylene-propylene-styrene block copolymers (SEEPS), styrene-ethylene-ethylene-propylene-styrene block copolymers, styrene-ethylene-butylene-styrene block copolymers, and polystyrene-poly(ethyrene-ethyrene/propylene) block-polystyrene block copolymers (SEEPS-OH) whose end is modified with a hydroxyl group.
